(19) United States
(12) Patent Application Publication
(10) Pub. No.: US 2014/0048117 A1
(43) Pub. Date: Feb. 20, 2014

(54) SOLAR ENERGY SYSTEMS USING EXTERNAL REFLECTORS

(71) Applicant: Pingrong Yu, Santa Clara, CA (US)

(72) Inventor: Pingrong Yu, Santa Clara, CA (US)

(73) Assignee: PU NI TAI YANG NENG (HANGZHOU) CO., LIMITED, Hangzhou (CN)

(21) Appl. No.: 13/587,765

(22) Filed: Aug. 16, 2012

(51) Int. Cl. H01L 31/052

(52) U.S. Cl. 136/246

(57) ABSTRACT

A concentrating photovoltaic system includes a condenser system and photovoltaic modules. The condenser system includes a quasi-Fresnel concave lens coated with an antireflection film and a reflector coated with a reflective film. The reflector is located between the quasi-Fresnel concave lens and the PV modules. A high refractive index optical resin is filled between the quasi-Fresnel concave lens and the photovoltaic modules. The quasi-Fresnel concave lens has a flat or hemispherical structure; the reflector can be placed horizontally, or at an angle to form a light condensing funnel.

### BACKGROUND OF THE INVENTION

1. Field of the Invention

This invention relates to the field of solar energy technology, in particular to a photovoltaic system using optical refractors and reflectors.

2. Description of the Related Art

Solar energy, typically used either to generate electricity or heat, has been widely applied and the demand is still growing. The technology of electricity generation by photovoltaic (PV) devices was developed over the past few decades. Commercial PV systems range in size from mega watt (MW) power plants to rooftop power systems to portable electronics. However, the cost of solar energy conversion needs to be further reduced to make solar energy a more desirable choice of energy source. Currently, electricity generated by solar power is typically a few times more expensive than electricity generated by burning fossil fuels.

Light transmitters or reflectors have been explored as means to reduce solar energy conversion cost. For example, reflective optical components can be designed to concentrate light into a small volume or area. U.S. Pat. No. 4,011,858 describes a parabolic reflector that concentrates sun light onto a water pipe located at the focal point of the parabolic reflector. However, these non-imaging reflectors are designed to concentrate light onto a fairly small volume or area. In addition, since their shape is precisely defined, they can be relatively expensive to fabricate and/or install.

Transmitters usually use the Fresnel lens with point focused or line focused, which can focus the light on a small area of the cell. The efficiency of the Fresnel lens depends on its structural design. However, traditional Fresnel lens ignores the utilization of some light energy which is reflected through the air/lens interface, or which is reflected by the surface of the cell.

As a result of these drawbacks, there is a continuing need for better approaches to transmit and reflect light onto finished solar modules, e.g. a crystal silicon solar panel or a thin film (a-Si, CIGS, or CdTe) solar module with rigid or flexible substrate. It is generally desirable to develop better approaches to reduce solar energy conversion cost and/or to solve the challenges presented by limited size.

### SUMMARY OF THE INVENTION

A concentrating photovoltaic system using optical transmitters and reflectors has high utilization efficiency of solar energy, simple structure, low cost and is easy to fabrication.

The concentrating photovoltaic system includes a condenser system and photovoltaic modules. The condenser system includes a quasi-Fresnel concave lens coated with an antireflection film and a reflector coated with a reflective film. The reflector is located between the quasi-Fresnel concave lens and the PV modules. An optical resin with high refractive index is filled around the PV modules.

The material of the quasi-Fresnel concave lens may be glass or polyolefin resins, with a flat or hemispherical structure. The structure inside the concave lens has laddered grooves, with depth of 0.001 to 0.68 mm and angle of 0 to 60 degrees. This concave lens and the high refractive index optical resin constitute the condenser element, which can focus the incident light on the PV modules uniformly. A significant difference from traditional Fresnel lens is the design of the concave lens. Because the space between the lens and the photovoltaic modules is filled with the optical resin which has a refractive index greater than that of the lens, the structure of the quasi-Fresnel concave lens is needed to focus the light on to desired areas.

The material of the antireflection coating can be porous SiO₂ or MgF₂, which can increase the transmittance of the quasi-Fresnel concave lens. The interface between the antireflection coating and the quasi-Fresnel concave lens can increase the transmittance of the incident light and can help create secondary or multiple reflections and absorption by modules.

The reflector is consisted of a plastic shell and an inner wall coated with a reflective film. The reflective film is made of aluminum, silver or other metal-dielectric film. The light reflected outside the lens and from the cell (the PV module) can be collected by the reflector and gathered into the cell again. The reflector can be placed horizontally, or at an angle to form a light condensing funnel. In general, when the quasi-Fresnel lens is flat, the reflector is oblique; and when quasi-Fresnel lens is a structure of hemispherical-like, the reflector can be horizontal.

The optical resin with high refractive index could be epoxy or episulfide resin, the refractive index is between 1.6 and 1.7. The resin forms an interface with the lens, with a higher transmittance than a lens/air interface, which can improve the transmittance of the lens, thereby enhancing the absorption of light.

Compared with the conventional technology, this invention has the following useful technical effect:

(1) The antireflection coated in the quasi-Fresnel concave lens can improve light transmission significantly, while the interface formed by the reflective film and the quasi-Fresnel concave lens can make the light reflected by the cell or the reflector return again on the cell surface for secondary or multiple reflection absorption.

(2) The reflector with high reflectivity can reflect the light outside of the lens and the light unabsorbed by the cell on the PV modules repeatedly, which can improve the utilization of light.

(3) The optical resin with high refractive index filled in the space between the quasi-Fresnel concave lens and the reflector and photovoltaic modules can increase the transmittance of the interface formed by the quasi-Fresnel concave lens and the optical resin.

So the invention can enhance solar energy utilization and reduce the cost of photovoltaic system.

### BRIEF DESCRIPTION OF THE DRAWINGS

FIG. 1 schematically illustrates a conventional concentrator photovoltaic system using the point focus Fresnel lens as a condenser system.

FIG. 2 is a cross-section diagram of FIG. 1.

FIG. 3 schematically illustrates a conventional concentrator photovoltaic system using the line focus Fresnel lens as a condenser system.

FIG. 4 is a cross-section diagram of FIG. 3.

FIG. 5 schematically illustrates a quasi-Fresnel concave lens coated with antireflection coating useful in embodiments of this invention.

FIG. 6 is a cross-section diagram of FIG. 5.

FIG. 7 schematically illustrates a concentrator photovoltaic system according to a first embodiment of this invention.

FIG. 8 is a cross-section diagram of FIG. 7.

FIG. 9 schematically illustrates a concentrator photovoltaic system according to a second embodiment of this invention.

FIG. 10 schematically illustrates a concentrator photovoltaic system according to a third embodiment of this invention.

### DETAILED DESCRIPTION OF THE PREFERRED EMBODIMENTS

FIG. 1-4 schematically shows a concentrating photovoltaic system according to conventional technology using several Fresnel lens as a condenser.

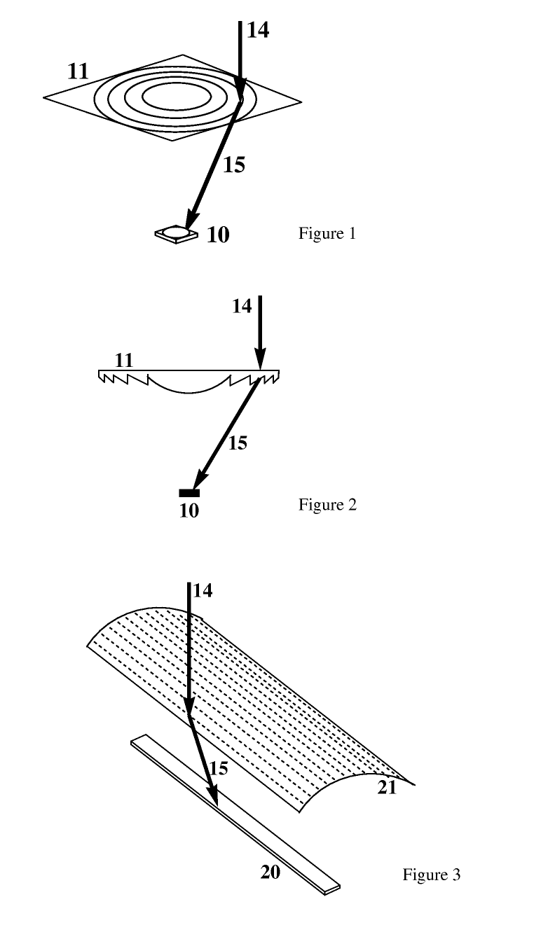

The concentrator photovoltaic system shown in FIG. 1 and FIG. 2 uses a point focused Fresnel lens 11 as a condenser and a single thin film cell 10 as a photovoltaic module.

The light 14 is gathered by the point focused Fresnel lens 11 in the thin film cell 10, and the refractive light 15 is concentrated in a circular area on the thin film cell 10. In this concentrating photovoltaic system, the concentration ratio depends on the circular area and the effective area of the point focused Fresnel lens 11.

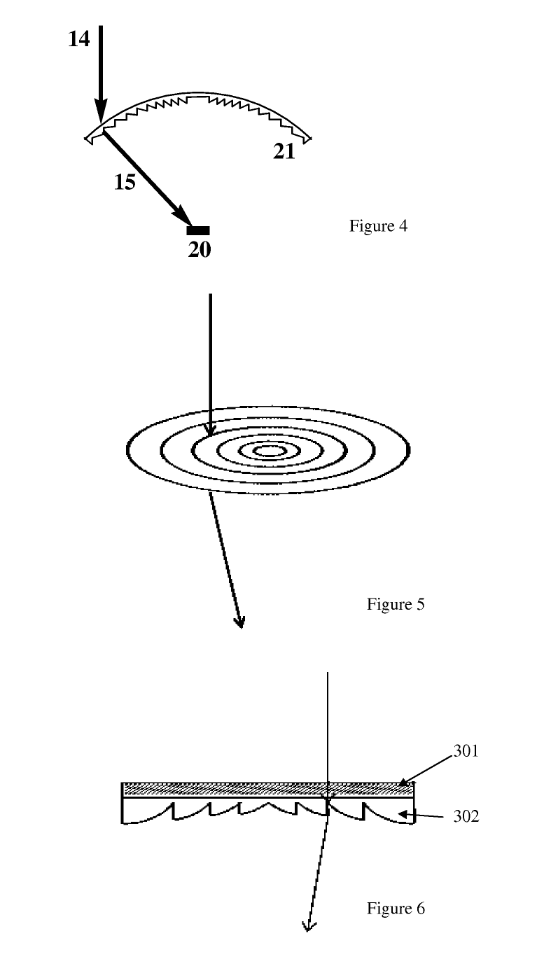

The concentrator photovoltaic system shown in FIG. 3 and FIG. 4 uses a line focused Fresnel lens 21 as a condenser and several linear arrangement of thin film cells as a photovoltaic module 20. The light 14 is gathered by the point focused Fresnel lens 21, and the refractive light 15 is concentrated on to the thin film cell 20. In this concentrating photovoltaic system, the concentration ratio is the rate of the effective area of the Fresnel lens 21 and the area of the thin film cell 20.

In these two systems, some light can be lost by the reflectivity of the concave lens or solar cell surface, and the systems are unable to make full use of the solar energy.

The invention will now be detailed describe in the following embodiments and drawings; however, the invention is not limited to the particular embodiments.

### First Embodiment

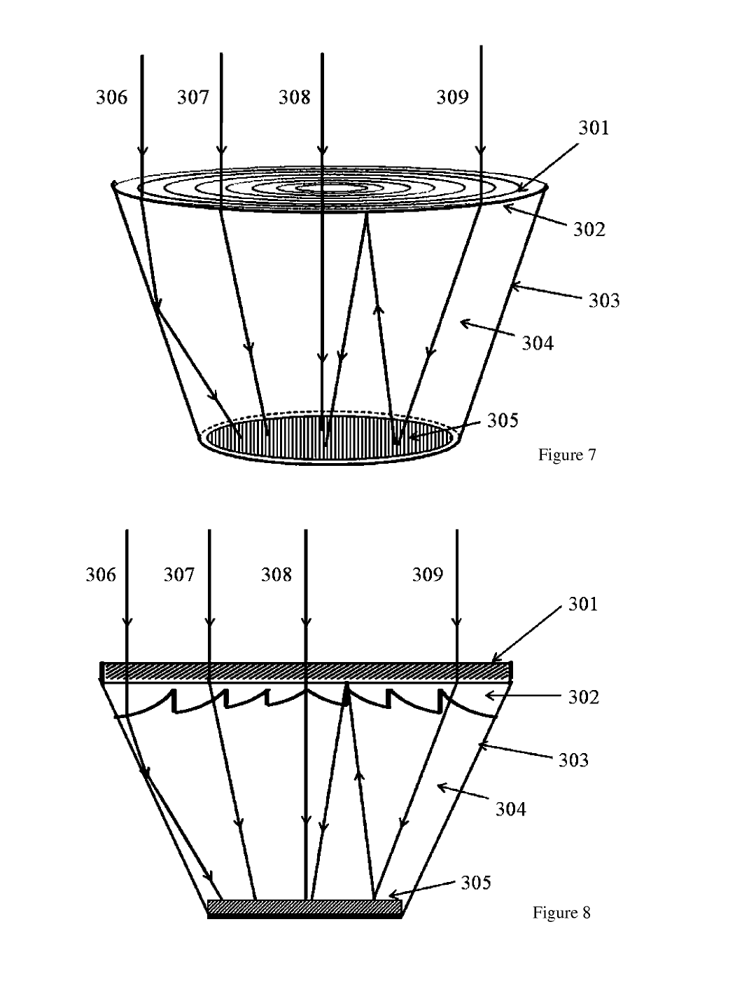

The concentrating photovoltaic systems shown in FIGS. 7-8 includes anti-reflection film 301, quasi-Fresnel concave lens 302, reflector 303, filling material 304 and PV modules 305. The lens has a substantially planar shape. The film 301 is located above the lens 302 and may be coated on the upper flat surface of the lens. The reflector 303 is disposed below the lens 302, and the PV modules 305 are disposed below the reflector. The material of the anti-reflection film 301 may be porous SiO₂ or MgF₂, and the material of the quasi-Fresnel lens 302 may be glass. The interface between the antireflection film 301 and the quasi-Fresnel concave lens 302 can increase the transmittance of the incident light through the quasi-Fresnel concave lens 302, and can also help create secondary or multiple reflections to reflect light back to the PV modules. The inner surface of the reflector 303 may be coated with a reflective film, which may be Al, Ag, or other metal-dielectric film. The reflector 303 has the shape of a truncated cone which constitutes a condenser funnel, with the lens 302 located near the larger opening of the funnel and the PV modules located near the smaller opening of the funnel. The shell of the funnel (reflector 303) may be a plastic material, and the filling material 304 that fills the funnel may be an optical resin with epoxy or episulfide. The PV modules 305 can be any type of solar cell.

When beams of light illuminate on the concentrating photovoltaic system, the transmission path of various beams can be indicated by lines 306, 307, 308 and 309. In the illustrated example, the incident light 306 is perpendicular to the antireflection film 301, and is refracted by the quasi-Fresnel concave lens 302 to reach the reflector 303, and then reflected by the reflector 303 to the PV modules 305. The incident light 307 is perpendicular to the antireflection film 301 and is refracted by the quasi-Fresnel concave lens 302 to reach the PV modules 305 directly without being reflected by the reflector 303. The incident light 308 pass through the quasi-Fresnel concave lens 302 without significant refraction and irradiates vertically on to the PV modules 305. The incident light 309 is gathered on to the PV modules 305 by the quasi-Fresnel concave lens 302, and is shown as being reflected partly by the PV modules 305. When this part of reflected light arrives at the interface of the quasi-Fresnel concave lens 302 and the antireflection film 301 located above the lens, because the refractive index of quasi-Fresnel concave lens 302 is higher than that of the antireflection film 301, this light is reflected back on to the PV modules 305. As a result, the solar energy incident to the concentrating photovoltaic system can be absorbed as much as possible.

In the above system, as a result of antireflection film 301, the reflectivity of the quasi-Fresnel concave lens 302 can be improved from 92% to 98%. Between 3-8% of light which is reflected by the modules 305 can be reflected by the reflector 303 or the interface formed by quasi-Fresnel concave lens and antireflection film 301 and returned to the modules again.

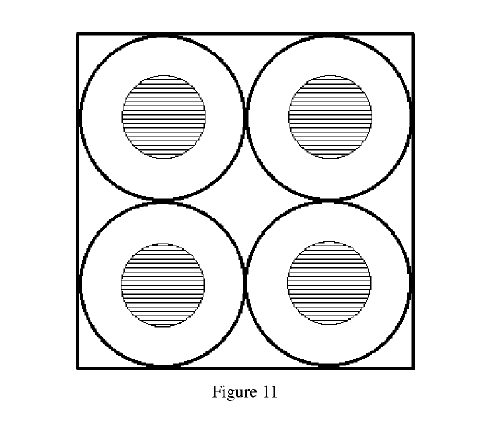

FIGS. 5 and 6 show the structure of quasi-Fresnel concave lens 302 coated with antireflection coating 301. The material of the quasi-Fresnel concave lens may be glass or polyolefin resins, with a generally flat or hemispherical structure (a flat structure is shown in FIGS. 5 and 6; a hemispherical structure is shown in FIG. 10, described later). The structure inside the concave lens has laddered grooves, with depths of 0.001 to 0.68 mm and angles of 0 to 60 degrees. The lens is concave in that the edge is generally thicker than the center area. This concave lens and the high refractive index optical resin (see FIGS. 7 and 8) constitute the condenser element, which can focus the incident light on the PV modules uniformly. A significant difference between this lens and a traditional Fresnel lens is the design of the concave lens. Because the space between the lens and the photovoltaic modules is filled with the optical resin which has a refractive index greater than that of the lens, the structure of the quasi-Fresnel concave lens is needed to focus the light on to desired areas.

### Second Embodiment

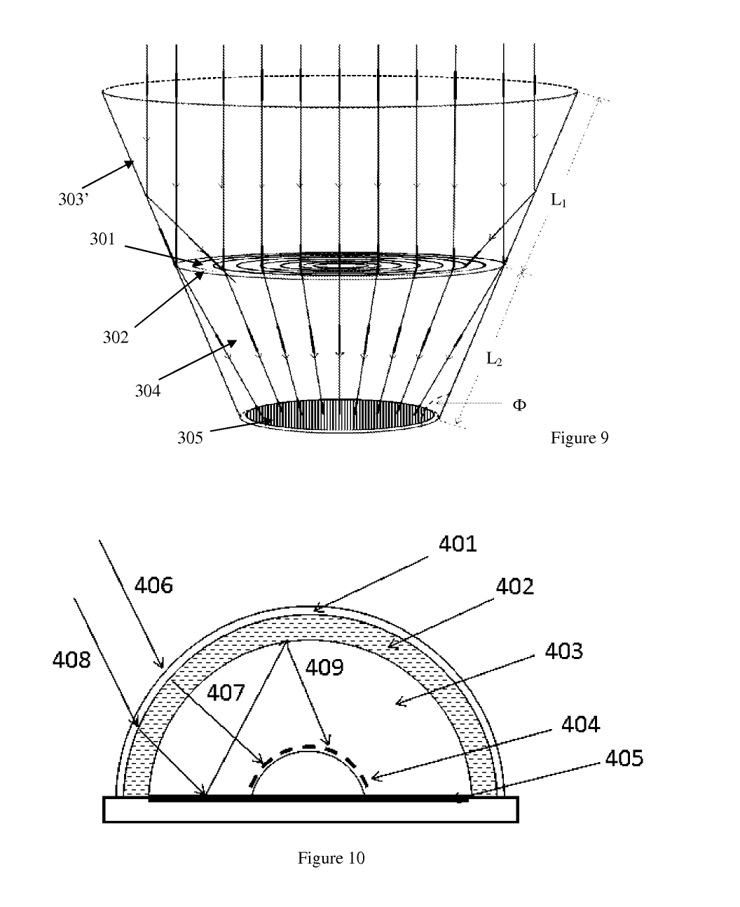

A concentrator photovoltaic system shown in FIG. 9 includes a condenser system and photovoltaic modules. This system is similar to the one shown in FIGS. 7-8 in that it includes anti-reflection film 301, quasi-Fresnel concave lens 302, reflector 303′, filling material 304 and PV modules 305, the difference being the anti-reflection film 301 and quasi-Fresnel concave lens 302 are located mid-way inside the truncated-cone shaped reflector 303′. If the distance from the top of the reflector 303′ to the quasi-Fresnel concave lens 302 is L1, the distance from the quasi-Fresnel concave lens to the photovoltaic module 305 is L2, and the angle between the sidewall of the reflector 303′ and the photovoltaic modules is Φ, the concentration ratio of the entire condenser system can be adjusted by adjusting the size of the L1/L2 ratio and the angle Φ. The adjustment range of the angle Φ is about 120°-150°.

The above system can effectively improve the incident flux density and reduce the size of the quasi-Fresnel concave lens compared to the first embodiment, which can greatly reduce the system cost.

In both the first and the second embodiments, the quasi-Fresnel concave lens 302 is located at a wider part of the truncated-cone shaped reflector 303/303′ and the photovoltaic modules are located at a narrower part of the truncated-cone shape.

### Third Embodiment

A concentrator photovoltaic system shown in FIG. 10 includes a condenser system and photovoltaic modules. The condenser system includes a hemispherical quasi-Fresnel lens 402 coated with anti-reflection film 401 and a planar reflector 405. The PV module 404 is located in the focal sphere of the hemispherical Fresnel lens 402, and a high refractive index optical resin 403 is filled between the quasi-Fresnel lens and the PV module. The PV modules 404 can be composed of one flexible cell or many flat cells. The reflector 405 is disposed in a plane at the base of the hemispherical quasi-Fresnel lens 402 and covers substantially the entire areas between the PV module and the circular base of the quasi-Fresnel lens. In the illustrated example, the incident light 406 passes through the condenser components (anti-reflection film 401 and lens 402) to form a beam 407 illuminating on the cell (PV module) 404. The incident light 408 is refracted to the reflector 405 by the condenser components, then goes through secondary reflection by the reflector 405 to become beam 409, which is finally absorbed by the cell.

This system can effectively improve the incident flux density, and significantly improve the utilization of light energy

In the above embodiments, the PV modules may be thin film solar cells or crystalline silicon solar cells, and the cell(s) may have a rigid substrate or a flexible substrate.

In the above embodiments, the light reflected outside the lens and from the PV module can be collected by the reflector and gathered into the cell again. The reflector can be placed horizontally (third embodiment), or at an angle so a light condensing funnel formed (first and second embodiments). In general, when the quasi-Fresnel lens is flat, the reflector is oblique; and when quasi-Fresnel lens is a structure of hemispherical-like, the reflector can be horizontal.

In the above embodiments, the optical resin 304 with high refractive index may be epoxy or episulfide resin, and its refractive index may be between 1.6 and 1.7. The resin 304 forms an interface with the lens 302, with a higher transmittance than a lens/air interface, which can improve the transmittance of the lens, thereby enhancing the absorption of light.

### Fourth Embodiment

As shown in FIG. 11, a concentrator photovoltaic array may be formed by a plurality of concentrator photovoltaic systems of the first, second and/or third embodiment. Such an array can significantly improve the light utilization, and can reduce the cost of power generation.

1. A concentrating photovoltaic system comprising:
a condenser system including:
a quasi-Fresnel concave lens; and
a reflector coated with a reflective film;
one or more photovoltaic modules, located on a side of the quasi-Fresnel concave lens, wherein the reflector is disposed to reflect light from the quasi-Fresnel concave lens to the photovoltaic modules; and
a high refractive index optical resin completely filling a space bound by the reflector and between the quasi-Fresnel concave lens and the photovoltaic modules, wherein the optical resin is in contact with both the quasi-Fresnel concave lens and the photovoltaic modules.

2. The concentrating photovoltaic system of claim 1, wherein the photovoltaic modules include thin film solar cell or crystalline silicon solar cell and have a rigid substrate or a flexible substrate.

3. The concentrating photovoltaic system of claim 1, wherein the antireflection film is made of porous SiO₂ or MgF₂.

4. (canceled)

5. The concentrating photovoltaic system of claim 1, wherein the reflective film may be Al or Ag or a metal dielectric film.

6. (canceled)

7. The concentrating photovoltaic system of claim 1, wherein the quasi-Fresnel concave lens is a hemispherical structure, wherein the photovoltaic modules are located in a focal sphere of the hemispherical quasi-Fresnel concave lens, and wherein the reflector is flat and is disposed in a plane at a base of the hemispherical quasi-Fresnel concave lens between the photovoltaic modules and the quasi-Fresnel concave lens.

8. The concentrating photovoltaic system of claim 1, wherein a refractive index of the optical resin is between 1.6 and 1.7.

9. The concentrating photovoltaic system of claim 1, wherein the quasi-Fresnel concave lens is flat, and wherein the reflector is shaped as a truncated cone with the quasi-Fresnel concave lens located at a wider part of the truncated cone and the photovoltaic modules located at a narrower part of the truncated cone.

10. The concentrating photovoltaic system of claim 1, wherein the quasi-Fresnel concave lens is coated with an antireflection film on one side, and has a structure of laddered grooves with depth of 0.001 to 0.68 mm and angle of 0 to 60 degrees on another side, and wherein the one or more photovoltaic modules, located on a side of the quasi-Fresnel concave lens facing the laddered grooves and opposite the antireflection film.

11. The concentrating photovoltaic system of claim 1, wherein the optical resin is made of a material which is different from a material of the quasi-Fresnel concave lens.
